(19) United States
(12) Patent Application Publication
(10) Pub. No.: US 2026/0293549 A1
(43) Pub. Date: Sep. 24, 2026

(54) DEVICE STRUCTURE WITH FERROELECTRIC LAYER

(71) Applicant: TAIWAN SEMICONDUCTOR MANUFACTURING COMPANY, LTD., Hsinchu (TW)

(72) Inventors: Oreste MADIA, Bruxelles (BE); Georgios VELLIANITIS, Heverlee (BE)

(73) Assignee: TAIWAN SEMICONDUCTOR MANUFACTURING COMPANY, LTD., Hsinchu (TW)

(21) Appl. No.: 19/692,212

(22) Filed: May 29, 2026

Related U.S. Application Data
(62) Division of application No. 17/732,873, filed on Apr. 29, 2022, now Pat. No. 12,648,375.

(51) Int. Cl. H10P 14/692; H10D 64/01; H10D 64/68; H10P 14/60

(52) U.S. Cl. CPC H10P 14/69392; H10D 64/033; H10D 64/691; H10P 14/6544

(57) ABSTRACT

A device structure is provided. The device structure includes a substrate and a carbon-containing layer over the substrate. The device structure also includes a crystallized ferroelectric layer over the carbon-containing layer and a material layer interfacing the crystallized ferroelectric layer. The material layer and the carbon-containing layer are made of different materials.

### PRIORITY CLAIM AND CROSS-REFERENCE

This Application is a Divisional of U.S. Application No. 17/732,873, filed on Apr. 29, 2022, the entirety of which is incorporated by reference herein.

### BACKGROUND

The integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1E are cross-sectional views of various stages of a process for forming a portion of a device structure, in accordance with some embodiments.

FIGS. 2A-2C are cross-sectional views of various stages of a process for forming a portion of a device structure, in accordance with some embodiments.

FIGS. 3A-3D are cross-sectional views of various stages of a process for forming a portion of a device structure, in accordance with some embodiments.

FIGS. 4A-4E are cross-sectional views of various stages of a process for forming a portion of a device structure, in accordance with some embodiments.

FIGS. 5A-5F are cross-sectional views of various stages of a process for forming a portion of a device structure, in accordance with some embodiments.

FIG. 6 is a top view of an intermediate stage of a process for forming a portion of a device structure, in accordance with some embodiments.

FIGS. 7A-7F are cross-sectional views of various stages of a process for forming a portion of a device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the device structure. Some of the features described below can be replaced or eliminated for different embodiments. Although some embodiments are discussed with operations performed in a particular order, these operations may be performed in another logical order.

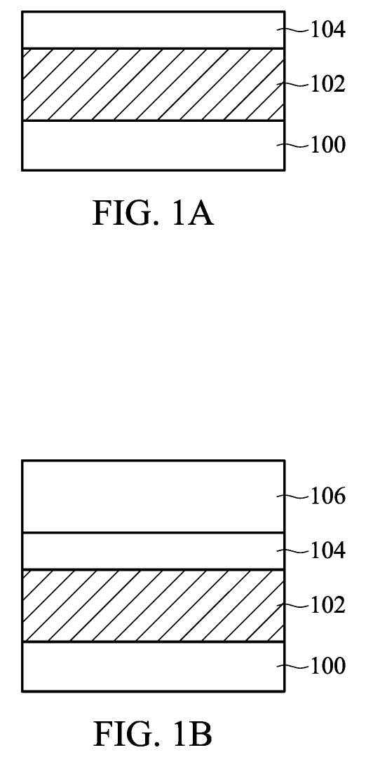

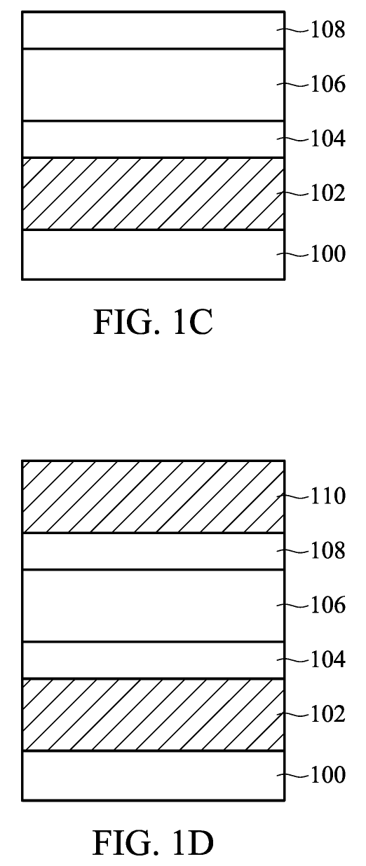

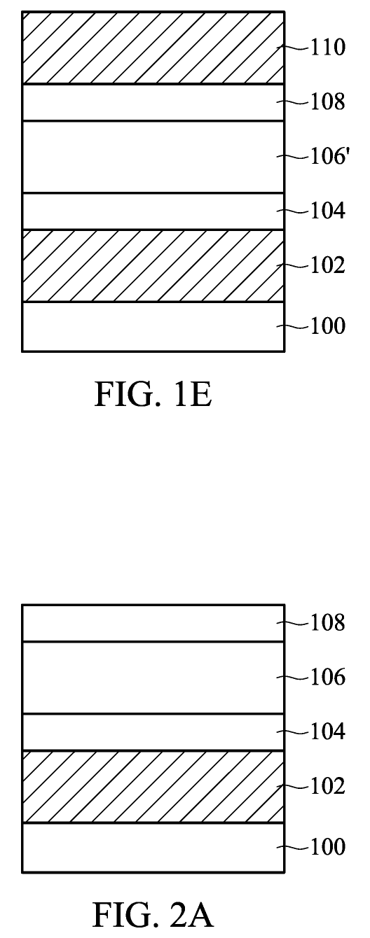

FIGS. 1A-1E are cross-sectional views of various stages of a process for forming a portion of a device structure, in accordance with some embodiments. As shown in FIG. 1A, a substrate 100 is received or provided. In some embodiments, the substrate 100 is a bulk semiconductor substrate, such as a semiconductor wafer. The substrate 100 may include silicon or other elementary semiconductor materials such as germanium. The substrate 100 may include an interconnection structure with multiple dielectric layers and multiple conductive features. In some other embodiments, the substrate 100 is a dielectric substrate such as a glass substrate.

As shown in FIG. 1A, a bottom electrode 102 is formed over the substrate 100, in accordance with some embodiments. In some embodiments, the bottom electrode 102 is formed over the interconnection structure of the substrate 100. In some other embodiments, the bottom electrode 102 is surrounded by the interconnection structure of the substrate 100.

In some embodiments, the bottom electrode 102 is made of or includes a metal-containing material. The bottom electrode 102 may be made of or include tungsten (W), tungsten carbide (WC), tungsten nitride (WN), aluminum (Al), aluminum nitride (AlN), titanium (Ti), titanium nitride (TiN), niobium (Nb), ruthenium (Ru), platinum (Pt), gold (Au), one or more other suitable materials, or a combination thereof. The formation of the bottom electrode 102 may involve one or more deposition processes, one or more patterning processes, and/or one or more planarization processes. For example, one or more damascene processes may be used to form the bottom electrode 102.

As shown in FIG. 1A, a carbon-containing layer 104 is deposited over the bottom electrode 102, in accordance with some embodiments. In some embodiments, the carbon-containing layer 104 is in direct contact with the bottom electrode 102. In some embodiments, the carbon-containing layer 104 is a pure carbon layer. In some embodiments, the carbon-containing layer 104 is amorphous. The thickness of the carbon-containing layer 104 may be within a range from about 2 angstroms to about 10 nm. In some embodiments, the carbon-containing layer 104 has a lower coefficient of thermal expansion (CTE) than that of the bottom electrode 102. The CTE of the carbon-containing layer 104 may be within a range from about 10⁻⁷K⁻¹ to about 10⁻⁶K⁻¹.

The carbon-containing layer 104 may be deposited using a CVD process, an atomic layer deposition (ALD) process, a plasma enhanced chemical vapor deposition (PECVD) process, a plasma enhanced atomic layer deposition (PEALD) process, a PVD process, a molecular beam epitaxy process (MBE), one or more other applicable processes, or a combination thereof. The precursor gases used for forming the carbon-containing layer 104 may include one or more halogen- and carbon-containing gases and hydrogen. The formation of the carbon-containing layer 104 may further involve one or more patterning processes.

As shown in FIG. 1B, a ferroelectric layer 106 is deposited over the carbon-containing layer 104, in accordance with some embodiments. In some embodiments, the ferroelectric layer 106 is in direct contact with the carbon-containing layer 104. In some embodiments, the ferroelectric layer 106 is a hafnium-containing oxide layer. For example, the ferroelectric layer 106 is made of hafnium zirconium oxide (HZO). The atomic concentration of hafnium of the ferroelectric layer 106 may be within a range from about 30% to about 75%. In some embodiments, the ferroelectric layer 106 is amorphous.

The ferroelectric layer 106 may be deposited using an ALD process, a CVD process, one or more other applicable processes, or a combination thereof. The precursor gases used for forming the ferroelectric layer 106 may include a hafnium-containing gas such as hafnium chloride, dimethylamido hafnium, one or more other suitable precursors, or a combination thereof. The precursor gases used for forming the ferroelectric layer 106 may also include a zirconium-containing gas such as zirconium chloride, dimethylamido zirconium, one or more other suitable precursors, or a combination thereof. The precursor gases used for forming the ferroelectric layer 106 may further include oxidant such as oxygen, ozone, water, hydrogen peroxide, one or more other suitable oxidants, or a combination thereof. The formation of the ferroelectric layer 106 may further involve one or more patterning processes.

As shown in FIG. 1C, a carbon-containing layer 108 is deposited over the ferroelectric layer 106, in accordance with some embodiments. In some embodiments, the carbon-containing layer 108 is in direct contact with the ferroelectric layer 106. In some embodiments, the material and formation method of the carbon-containing layer 108 are the same as or similar to those of the carbon-containing layer 104. In some embodiments, the carbon-containing layer 108 is amorphous. The thickness of the carbon-containing layer 108 may be within a range from about 2 angstroms to about 10 nm. In some embodiments, the carbon-containing layer 108 has a lower coefficient of thermal expansion (CTE) than that of the ferroelectric layer 106. The CTE of the carbon-containing layer 108 may be within a range from about 10⁻⁷K⁻¹ to about 10⁻⁶K⁻¹.

As shown in FIG. 1D, a top electrode 110 is formed over the carbon-containing layer 108, in accordance with some embodiments. The material and formation method of the top electrode 110 may be the same as or similar to those of the bottom electrode 102. In some embodiments, the top electrode 110 is in direct contact with the carbon-containing layer 108.

As shown in FIG. 1E, the ferroelectric layer 106 is crystallized to form a crystallized ferroelectric layer 106’, in accordance with some embodiments. In some embodiments, the ferroelectric layer 106 is made of hafnium zirconium oxide. After the crystallization, the crystallized ferroelectric layer 106’ has a non-centrosymmetric polar orthorhombic phase. In some embodiments, the device structure shown in FIG. 1E functions as a ferroelectric tunnel junction (FTJ) memory device.

In some embodiments, the crystallization of the ferroelectric layer 106 involves thermally annealing the ferroelectric layer 106. In some embodiments, the ferroelectric layer 106 and the carbon-containing layers 104 and 108 are annealed simultaneously to form the crystallized ferroelectric layer 106’.

The annealing temperature may be within a range from about 150 degrees C to about 900 degrees C. The annealing atmosphere gas may include N₂, Ar, N₂H₂, O₂, H₂O, He, one or more other suitable gases, or a combination thereof. The annealing time may be within a range from about 1 second to about 6 hours.

As mentioned above, in some embodiments, the carbon-containing layers 104 and 108 have a low coefficient of thermal expansion. During the cooling step following the annealing process, the carbon-containing layers 104 and 108 may function as stress layers that induce in-plane tensile strain to the ferroelectric layer 106. The constraint of the carbon-containing layers 104 and 108 may facilitate to the growth of the orthorhombic phase of the crystallized ferroelectric layer 106’. The remnant polarization and the endurance of the crystallized ferroelectric layer 106’ may be improved.

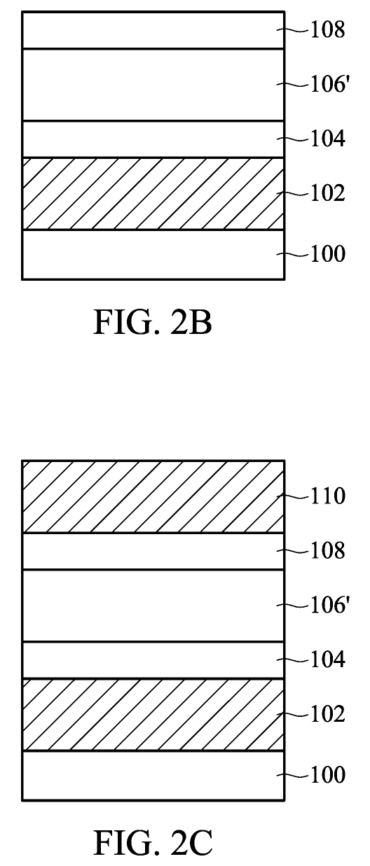

Many variations and/or modifications can be made to embodiments of the disclosure. FIGS. 2A-2C are cross-sectional views of various stages of a process for forming a portion of a device structure, in accordance with some embodiments. As shown in FIG. 2A, a structure that is the same as or similar to the structure shown in FIG. 1C is formed.

As shown in FIG. 2B, the ferroelectric layer 106 is crystallized to form the crystallized ferroelectric layer 106’, in accordance with some embodiments. In some embodiments, the crystallization of the ferroelectric layer 106 involves thermally annealing the ferroelectric layer 106. In some embodiments, the ferroelectric layer 106 and the carbon-containing layers 104 and 108 are annealed simultaneously to form the crystallized ferroelectric layer 106’.

The annealing temperature may be within a range from about 150 degrees C to about 900 degrees C. The annealing atmosphere gas may include N₂, Ar, N₂H₂, O₂, H₂O, He, one or more other suitable gases, or a combination thereof. The annealing time may be within a range from about 1 second to about 6 hours.

Afterwards, a top electrode 110 is formed over the carbon-containing layer 108, as shown in FIG. 2C in accordance with some embodiments. The material and formation method of the top electrode 110 may be the same as or similar to those of the top electrode 110 illustrated in FIG. 1D.

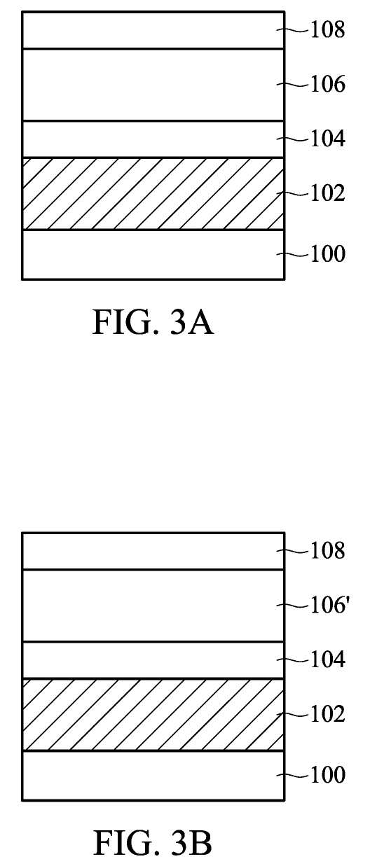

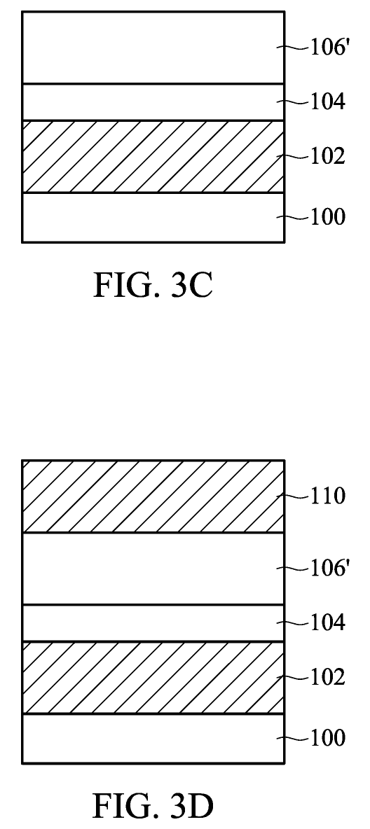

Many variations and/or modifications can be made to embodiments of the disclosure. FIGS. 3A-3D are cross-sectional views of various stages of a process for forming a portion of a device structure, in accordance with some embodiments. As shown in FIG. 3A, a structure that is the same as or similar to the structure shown in FIG. 1C is formed. Afterwards, as shown in FIG. 3B, similar to the embodiments illustrated in FIG. 2B, the ferroelectric layer 106 is crystallized to form the crystallized ferroelectric layer 106’, in accordance with some embodiments.

As shown in FIG. 3C, the carbon-containing layer 108 is removed after the formation of the crystallized ferroelectric layer 106’, in accordance with some embodiments. As a result, the crystallized ferroelectric layer 106’ is exposed. One or more etching processes may be used to remove the carbon-containing layer 108.

As shown in FIG. 3D, a top electrode 110 is formed over the crystallized ferroelectric layer 106’, in accordance with some embodiments. The material and formation method of the top electrode 110 may be the same as or similar to those of the top electrode 110 illustrated in FIG. 1D. In some embodiments, the top electrode 110 is in direct contact with the crystallized ferroelectric layer 106’.

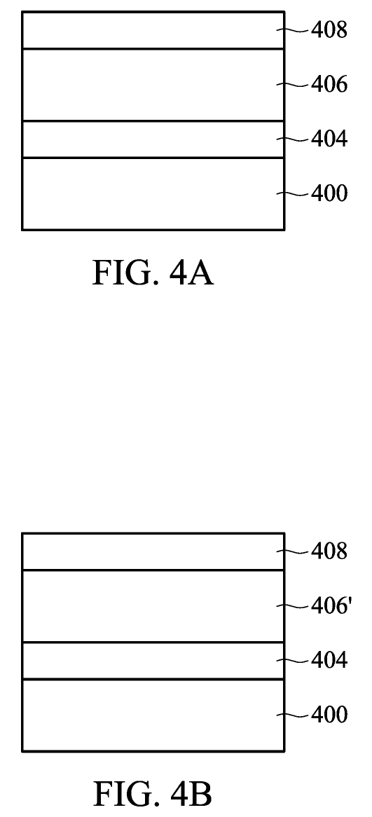

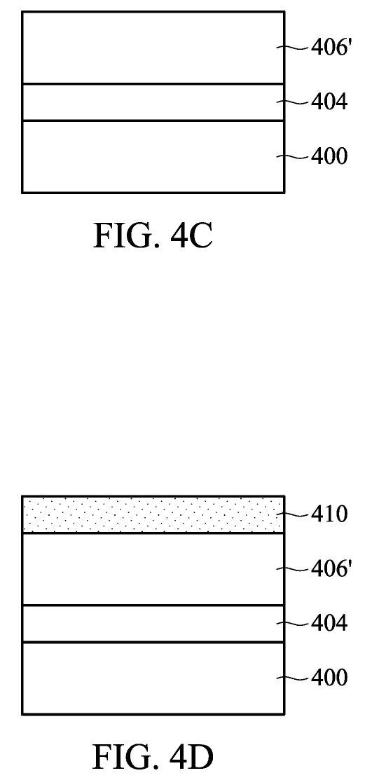

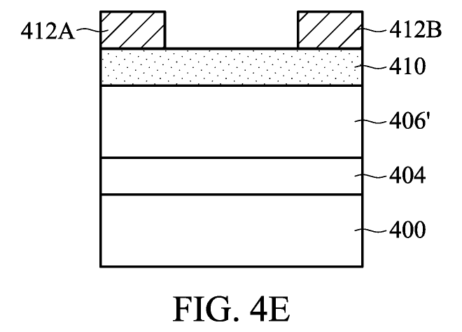

Many variations and/or modifications can be made to embodiments of the disclosure. FIGS. 4A-4E are cross-sectional views of various stages of a process for forming a portion of a device structure, in accordance with some embodiments. As shown in FIG. 4A, a substrate 400 is provided and received. The substrate 400 may be the same as or similar to the substrate 100 illustrated in FIG. 1A.

Afterwards, a carbon-containing layer 404 is formed over the substrate 400, as shown in FIG. 4A in accordance with some embodiments. In some embodiments, the carbon-containing layer 404 is a pure carbon layer. In some embodiments, the carbon-containing layer 404 is amorphous. The thickness of the carbon-containing layer 404 may be within a range from about 2 angstroms to about 10 nm. In some embodiments, the carbon-containing layer 404 has a lower coefficient of thermal expansion (CTE) than that of the bottom electrode 102. The CTE of the carbon-containing layer 404 may be within a range from about 10⁻⁷K⁻¹ to about 10⁻⁶K⁻¹.

The carbon-containing layer 404 may be deposited using a CVD process, an atomic layer deposition (ALD) process, a plasma enhanced chemical vapor deposition (PECVD) process, a plasma enhanced atomic layer deposition (PEALD) process, a PVD process, a molecular beam epitaxy process (MBE), one or more other applicable processes, or a combination thereof. The precursor gases used for forming the carbon-containing layer 404 may include one or more halogen- and carbon-containing gases and hydrogen. The formation of the carbon-containing layer 404 may further involve one or more patterning processes.

As shown in FIG. 4A, a ferroelectric layer 406 is then formed over the carbon-containing layer 404, in accordance with some embodiments. In some embodiments, the ferroelectric layer 406 is in direct contact with the carbon-containing layer 404. In some embodiments, the ferroelectric layer 406 is a hafnium-containing oxide layer. For example, the ferroelectric layer 406 is made of hafnium zirconium oxide (HZO). The atomic concentration of hafnium of the ferroelectric layer 406 may be within a range from about 30% to about 75%. In some embodiments, the ferroelectric layer 406 is amorphous.

The ferroelectric layer 406 may be deposited using an ALD process, a CVD process, one or more other applicable processes, or a combination thereof. The precursor gases used for forming the ferroelectric layer 406 may include a hafnium-containing gas such as hafnium chloride, dimethylamido hafnium, one or more other suitable precursors, or a combination thereof. The precursor gases used for forming the ferroelectric layer 406 may also include a zirconium-containing gas such as zirconium chloride, dimethylamido zirconium, one or more other suitable precursors, or a combination thereof. The precursor gases used for forming the ferroelectric layer 406 may further include oxidant such as oxygen, ozone, water, hydrogen peroxide, one or more other suitable oxidants, or a combination thereof. The formation of the ferroelectric layer 406 may further involve one or more patterning processes.

Afterwards, a carbon-containing layer 408 is formed over the ferroelectric layer 406, as shown in FIG. 4A in accordance with some embodiments. In some embodiments, the carbon-containing layer 408 is in direct contact with the ferroelectric layer 406. In some embodiments, the material and formation method of the carbon-containing layer 408 are the same as or similar to those of the carbon-containing layer 104. In some embodiments, the carbon-containing layer 408 is amorphous. The thickness of the carbon-containing layer 408 may be within a range from about 2 angstroms to about 10 nm. In some embodiments, the carbon-containing layer 408 has a lower coefficient of thermal expansion (CTE) than that of the ferroelectric layer 106. The CTE of the carbon-containing layer 408 may be within a range from about 10⁻⁷K⁻¹ to about 10⁻⁶K⁻¹.

As shown in FIG. 4B, the ferroelectric layer 406 is crystallized to form a crystallized ferroelectric layer 406’, in accordance with some embodiments. In some embodiments, the ferroelectric layer 406 is made of hafnium zirconium oxide. After the crystallization, the crystallized ferroelectric layer 406’ has a non-centrosymmetric polar orthorhombic phase. In some embodiments, the crystallization of the ferroelectric layer 406 involves thermally annealing the ferroelectric layer 406. In some embodiments, the ferroelectric layer 406 and the carbon-containing layers 404 and 408 are annealed simultaneously to form the crystallized ferroelectric layer 406’.

The annealing temperature may be within a range from about 150 degrees C to about 900 degrees C. The annealing atmosphere gas may include N₂, Ar, N₂H₂, O₂, H₂O, He, one or more other suitable gases, or a combination thereof. The annealing time may be within a range from about 1 second to about 6 hours.

As mentioned above, in some embodiments, the carbon-containing layers 104 and 108 have a low coefficient of thermal expansion. During the cooling step following the annealing process, the carbon-containing layers 404 and 408 may function as stress layers that induce in-plane tensile strain to the ferroelectric layer 406. Under the constraint of the carbon-containing layers 404 and 408, the growth of the orthorhombic phase of the crystallized ferroelectric layer 406’ may be facilitated.

As shown in FIG. 4C, the carbon-containing layer 408 is removed after the formation of the crystallized ferroelectric layer 406’, in accordance with some embodiments. As a result, the crystallized ferroelectric layer 406’ is exposed. One or more etching processes may be used to remove the carbon-containing layer 408.

As shown in FIG. 4D, a channel layer 410 is formed over the crystallized ferroelectric layer 406’, in accordance with some embodiments. In some embodiments, the channel layer 410 is an oxide semiconductor layer. In some embodiments, the channel layer 410 is in direct contact with the crystallized ferroelectric layer 406’.

The channel layer 410 may be made of or include an n-type semiconductor material such as indium gallium zinc oxide (IGZO), indium zinc oxide (IZO), indium oxide (InO), indium tin oxide (ITO), indium tungsten oxide (IWO), one or more other suitable materials, or a combination thereof. Alternatively, the channel layer 410 may be made of or include a p-type semiconductor material such as copper oxide (CuO), nickel oxide (NiO), tin oxide (SnO), one or more other suitable materials, or a combination thereof. The channel layer 410 may be deposited using a CVD process, an ALD process, one or more other applicable processes, or a combination thereof. The formation of the channel layer 410 may further include one or more patterning processes.

As shown in FIG. 4E, source/drain electrodes 412A and 412B are formed, in accordance with some embodiments. The source/drain electrodes 412A and 412B are electrically connected to the channel layer 410. In some embodiments, the source/drain electrodes 412A and 412B are made of one or more metal materials. The formation of the source/drain electrodes 412A and 412B may include one or more deposition processes and one or more patterning processes. In some embodiments, the device structure shown in FIG. 4E functions as a back-gated ferroelectric thin film transistor (Fe-TFT). The crystallized ferroelectric layer 406’ may function as a gate dielectric layer, and the carbon-containing layer 404 may function as a gate electrode.

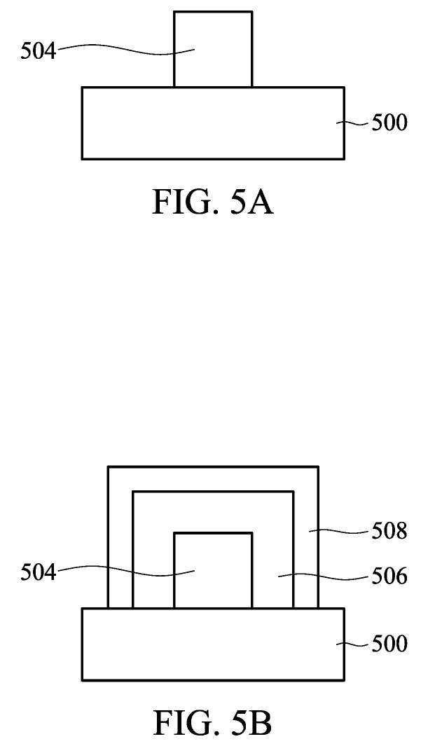

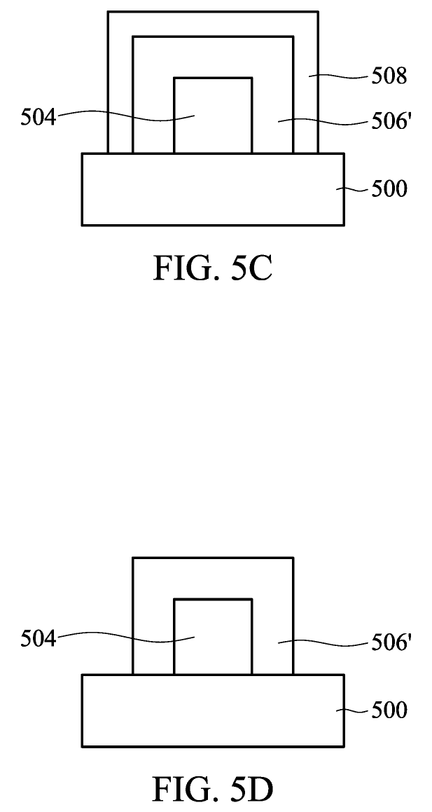

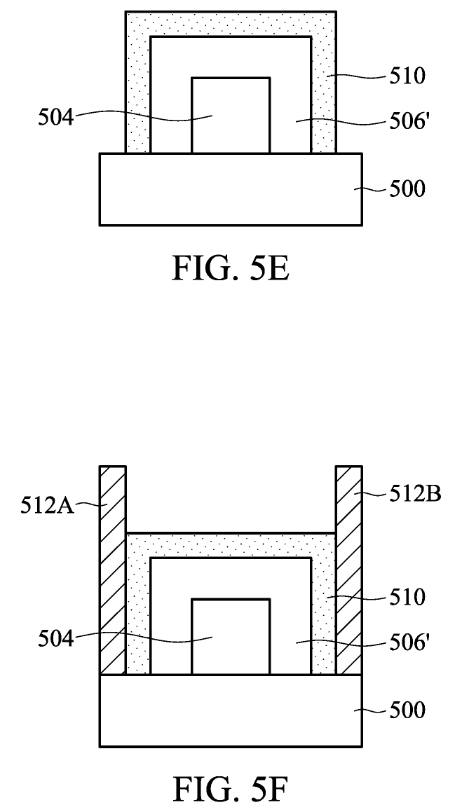

Many variations and/or modifications can be made to embodiments of the disclosure. FIGS. 5A-5F are cross-sectional views of various stages of a process for forming a portion of a device structure, in accordance with some embodiments. As shown in FIG. 5A, a substrate 500 is provided or received. The substrate 500 may be the same as or similar to the substrate 400 illustrated in FIG. 4A.

Afterwards, a carbon-containing strip 504 is formed over the substrate 500, as shown in FIG. 5A in accordance with some embodiments. In some embodiments, a carbon-containing layer is deposited over the substrate 500. Afterwards, the carbon-containing layer is patterned to form the carbon-containing strip 504. The material and formation method of the carbon-containing layer may be the same as or similar to those of the carbon-containing layer 404 as illustrated in FIG. 4A. After partially removing the carbon-containing layer, the remaining portion of the carbon-containing layer forms the carbon-containing strip 504. The carbon-containing strip 504 may function as the gate electrode of a three-dimensional thin film transistor (3D TFT).

As shown in FIG. 5B, a ferroelectric layer 506 is deposited over the carbon-containing strip 504 and the substrate 500, in accordance with some embodiments. The material and formation method of the ferroelectric layer 506 may be the same as or similar to those of the ferroelectric layer 406 as illustrated in FIG. 4A. In some embodiments, the ferroelectric layer 506 is in direct contact with the carbon-containing strip 504.

In some embodiments, the ferroelectric layer 506 is then patterned. One or more photolithography processes and one or more etching processes may be used to partially remove the ferroelectric layer 506. In some embodiments, the remaining portion of the ferroelectric layer 506 extends along the top and sidewalls of the carbon-containing strip 504. In some embodiments, in a top view, the remaining portion of the ferroelectric layer 506 partially covers the carbon-containing strip 504.

Afterwards, a carbon-containing layer 508 is deposited over the ferroelectric layer 506, as shown in FIG. 5B in accordance with some embodiments. The material and formation method of the ferroelectric layer 508 may be the same as or similar to those of the ferroelectric layer 408 as illustrated in FIG. 4A. In some embodiments, the carbon-containing layer 508 is in direct contact with the ferroelectric layer 506. In some embodiments, the carbon-containing layer 508 covers the ferroelectric layer 506.

As shown in FIG. 5C, the ferroelectric layer 506 is crystallized to form a crystallized ferroelectric layer 506’, in accordance with some embodiments. In some embodiments, the ferroelectric layer 506 is made of hafnium zirconium oxide. After the crystallization, the crystallized ferroelectric layer 506’ has a non-centrosymmetric polar orthorhombic phase. In some embodiments, the crystallization of the ferroelectric layer 506 involves thermally annealing the ferroelectric layer 506. In some embodiments, the ferroelectric layer 506, the carbon-containing strip 504, and the carbon-containing layer 508 are annealed simultaneously to form the crystallized ferroelectric layer 506’.

The annealing temperature may be within a range from about 150 degrees C to about 900 degrees C. The annealing atmosphere gas may include N₂, Ar, N₂H₂, O₂, H₂O, He, one or more other suitable gases, or a combination thereof. The annealing time may be within a range from about 1 second to about 6 hours.

In some embodiments, the carbon-containing strip 504 and the carbon-containing layer 508 have a low coefficient of thermal expansion. During the cooling step following the annealing process, the carbon-containing strip 504 and the carbon-containing layer 508 may function as stress layers that induce in-plane tensile strain to the ferroelectric layer 506. Under the constraint of the carbon-containing strip 504 and the carbon-containing layer 508, the growth of the orthorhombic phase of the crystallized ferroelectric layer 506’ may be facilitated.

As shown in FIG. 5D, the carbon-containing layer 508 is removed after the formation of the crystallized ferroelectric layer 506’, in accordance with some embodiments. As a result, the crystallized ferroelectric layer 506’ is exposed. One or more etching processes may be used to remove the carbon-containing layer 508.

As shown in FIG. 5E, a channel layer 510 is formed over the crystallized ferroelectric layer 506’, in accordance with some embodiments. In some embodiments, the channel layer 510 is an oxide semiconductor layer. In some embodiments, the channel layer 510 is in direct contact with the crystallized ferroelectric layer 506’.

The channel layer 510 may be made of or include an n-type semiconductor material such as indium gallium zinc oxide (IGZO), indium zinc oxide (IZO), indium oxide (InO), indium tin oxide (ITO), indium tungsten oxide (IWO), one or more other suitable materials, or a combination thereof. Alternatively, the channel layer 510 may be made of or include a p-type semiconductor material such as copper oxide (CuO), nickel oxide (NiO), tin oxide (SnO), one or more other suitable materials, or a combination thereof.

The channel layer 510 may be deposited using a CVD process, an ALD process, one or more other applicable processes, or a combination thereof. The formation of the channel layer 510 may further include one or more patterning processes. In some embodiments, in a top view, the channel layer 510 partially covers the crystallized ferroelectric layer 506’ and the carbon-containing strip 504.

As shown in FIG. 5F, source/drain electrodes 512A and 512B are formed, in accordance with some embodiments. The source/drain electrodes 512A and 512B are electrically connected to the channel layer 510. In some embodiments, the source/drain electrodes 512A and 512B are made of one or more metal materials. The formation of the source/drain electrodes 512A and 512B may include one or more deposition processes and one or more patterning processes. In some embodiments, the device structure shown in FIG. 5F functions as a three-dimensional thin film transistor (3D TFT). The crystallized ferroelectric layer 506’ may function as a gate dielectric layer, and the carbon-containing strip 504 may function as a gate electrode.

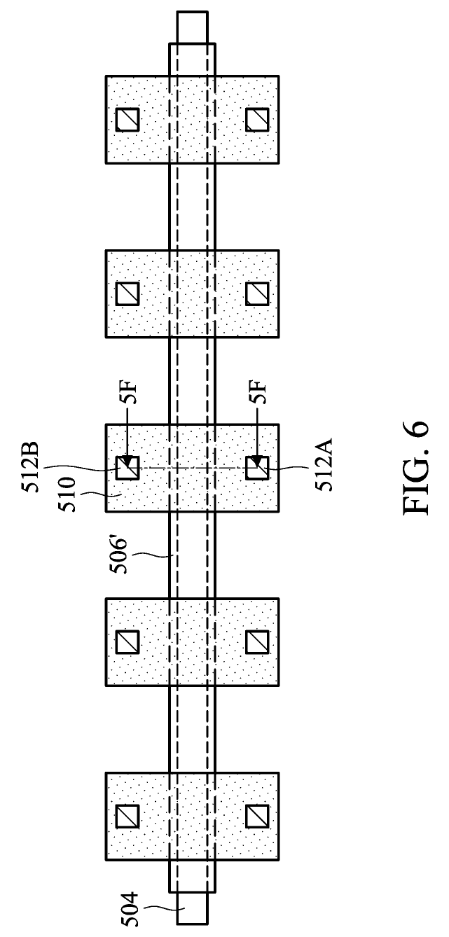

FIG. 6 is a top view of an intermediate stage of a process for forming a portion of a device structure, in accordance with some embodiments. In some embodiments, FIG. 5F is a cross-sectional view of the structure taken along the line 5F-5F in FIG. 6. In some embodiments, multiple channel layers 510 are formed to partially cover the crystallized ferroelectric layer 506’ and the carbon-containing strip 504, as shown in FIG. 6. In some embodiments, multiple electrodes are formed to provide electrical connections to the channel layers 510.

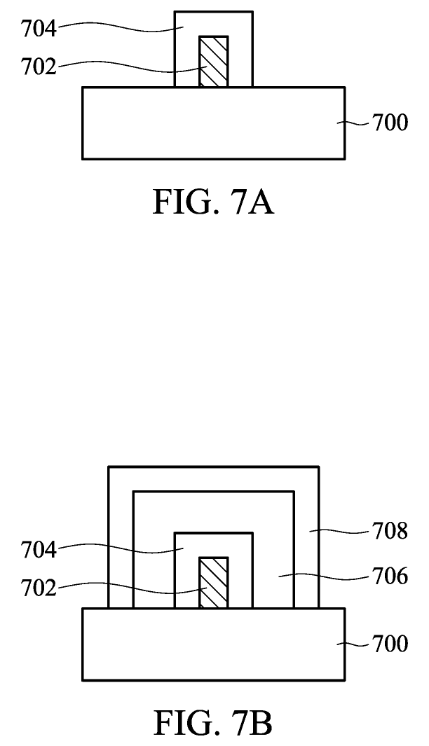

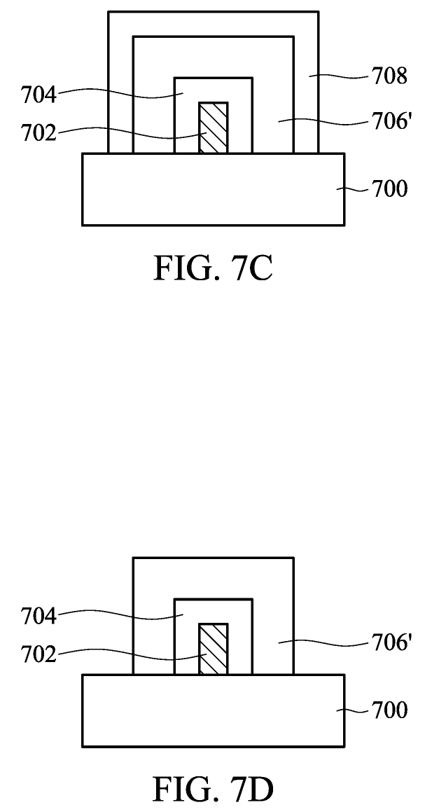

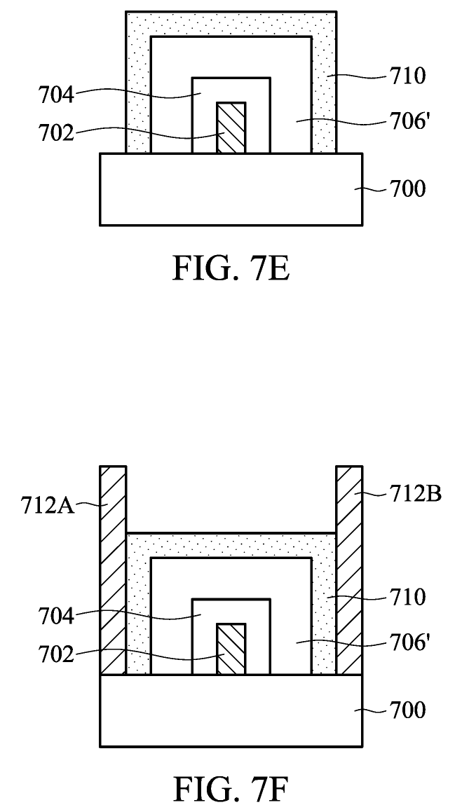

Many variations and/or modifications can be made to embodiments of the disclosure. FIGS. 7A-7F are cross-sectional views of various stages of a process for forming a portion of a device structure, in accordance with some embodiments. As shown in FIG. 7A, a substrate 700 is provided or received. The substrate 700 may be the same as or similar to the substrate 400 illustrated in FIG. 4A.

Afterwards, a metal gate strip 702 is formed over the substrate 700, as shown in FIG. 7A in accordance with some embodiments. The metal gate strip 702 may be made of or include tungsten (W), titanium nitride (TiN), ruthenium (Ru), one or more other suitable materials, or a combination thereof. In some embodiments, a metal-containing layer is deposited over the substrate 700. The metal-containing layer may be deposited using a PVD process, a CVD process, an ALD process, an electroplating process, an electrochemical deposition process, one or more other applicable processes, or a combination thereof. Afterwards, the metal-containing layer is patterned to form the metal gate strip 702. One or more photolithography processes and one or more etching processes may be used to pattern the metal-containing layer. After the partial removal of the metal-containing layer, the remaining portion of the metal layer forms the metal gate strip 702. The metal gate strip 702 may function as the gate electrode of a three-dimensional thin film transistor (3D TFT).

As shown in FIG. 7A, a carbon-containing layer 704 is then deposited over the metal gate strip 702 and the substrate 700, in accordance with some embodiments. The material and formation method of the carbon-containing layer 704 may be the same as or similar to those of the carbon-containing layer 404 as illustrated in FIG. 4A. In some embodiments, the carbon-containing layer 704 is in direct contact with the metal gate strip 702.

In some embodiments, the carbon-containing layer 704 is then patterned. One or more photolithography processes and one or more etching processes may be used to partially remove the carbon-containing layer 704. In some embodiments, the remaining portion of the carbon-containing layer 704 extends along the top and sidewalls of the metal gate strip 702. In some embodiments, in a top view, the remaining portion of the carbon-containing layer 704 partially covers the metal gate strip 702.

As shown in FIG. 7B, a ferroelectric layer 706 is deposited over the carbon-containing layer 704 and the substrate 700, in accordance with some embodiments. The material and formation method of the ferroelectric layer 706 may be the same as or similar to those of the ferroelectric layer 406 as illustrated in FIG. 4A. In some embodiments, the ferroelectric layer 706 is in direct contact with the carbon-containing layer 704.

In some embodiments, the ferroelectric layer 706 is then patterned. One or more photolithography processes and one or more etching processes may be used to partially remove the ferroelectric layer 706. In some embodiments, in a top view, the remaining portion of the ferroelectric layer 706 partially covers the carbon-containing layer 704.

Afterwards, a carbon-containing layer 708 is deposited over the ferroelectric layer 706, as shown in FIG. 7B in accordance with some embodiments. The material and formation method of the ferroelectric layer 708 may be the same as or similar to those of the ferroelectric layer 408 as illustrated in FIG. 4A. In some embodiments, the carbon-containing layer 708 is in direct contact with the ferroelectric layer 706. In some embodiments, the carbon-containing layer 708 covers the ferroelectric layer 706.

As shown in FIG. 7C, the ferroelectric layer 706 is crystallized to form a crystallized ferroelectric layer 706’, in accordance with some embodiments. In some embodiments, the ferroelectric layer 706 is made of hafnium zirconium oxide. After the crystallization, the crystallized ferroelectric layer 706’ has a non-centrosymmetric polar orthorhombic phase. In some embodiments, the crystallization of the ferroelectric layer 706 involves thermally annealing the ferroelectric layer 706. In some embodiments, the ferroelectric layer 706, the carbon-containing layer 704, and the carbon-containing layer 708 are annealed simultaneously to form the crystallized ferroelectric layer 706’.

The annealing temperature may be within a range from about 150 degrees C to about 900 degrees C. The annealing atmosphere gas may include N₂, Ar, N₂H₂, O₂, H₂O, He, one or more other suitable gases, or a combination thereof. The annealing time may be within a range from about 1 second to about 6 hours.

In some embodiments, the carbon-containing layer 704 and the carbon-containing layer 708 have a low coefficient of thermal expansion. During the cooling step following the annealing process, the carbon-containing layer 704 and the carbon-containing layer 708 may function as stress layers that induce in-plane tensile strain to the ferroelectric layer 706. Under the constraint of the carbon-containing layer 704 and the carbon-containing layer 708, the growth of the orthorhombic phase of the crystallized ferroelectric layer 706’ may be facilitated.

As shown in FIG. 7D, the carbon-containing layer 708 is removed after the formation of the crystallized ferroelectric layer 706’, in accordance with some embodiments. As a result, the crystallized ferroelectric layer 706’ is exposed. One or more etching processes may be used to remove the carbon-containing layer 708.

As shown in FIG. 7E, a channel layer 710 is formed over the crystallized ferroelectric layer 706’, in accordance with some embodiments. In some embodiments, the channel layer 710 is an oxide semiconductor layer. In some embodiments, the channel layer 710 is in direct contact with the crystallized ferroelectric layer 706’.

The channel layer 710 may be made of or include an n-type semiconductor material such as indium gallium zinc oxide (IGZO), indium zinc oxide (IZO), indium oxide (InO), indium tin oxide (ITO), indium tungsten oxide (IWO), one or more other suitable materials, or a combination thereof. Alternatively, the channel layer 710 may be made of or include a p-type semiconductor material such as copper oxide (CuO), nickel oxide (NiO), tin oxide (SnO), one or more other suitable materials, or a combination thereof.

The channel layer 710 may be deposited using a CVD process, an ALD process, one or more other applicable processes, or a combination thereof. The formation of the channel layer 710 may further include one or more patterning processes. In some embodiments, in a top view, the channel layer 710 partially covers the crystallized ferroelectric layer 706’ and the carbon-containing layer 704.

As shown in FIG. 7F, source/drain electrodes 712A and 712B are formed, in accordance with some embodiments. The source/drain electrodes 712A and 712B are electrically connected to the channel layer 710. In some embodiments, the source/drain electrodes 712A and 712B are made of one or more metal materials. The formation of the source/drain electrodes 712A and 712B may include one or more deposition processes and one or more patterning processes. In some embodiments, the device structure shown in FIG. 7F functions as a three-dimensional thin film transistor (3D TFT).

Embodiments of the disclosure form a device structure with a crystallized ferroelectric layer. Two carbon-containing stressor layers are used to assist in the growth of the crystallized ferroelectric layer. The carbon-containing stressor layers are formed to sandwich an amorphous ferroelectric layer. Afterwards, a thermal annealing process is performed to initiate the crystallization of the amorphous ferroelectric layer. During the cooling step following the annealing process, the carbon-containing stressor layers may induce in-plane tensile strain to the ferroelectric layer. The constraint of the carbon-containing layers may facilitate to the growth of the orthorhombic phase of the crystallized ferroelectric layer. The remnant polarization and the endurance of the crystallized ferroelectric layer may be improved. The performance and reliability of the device structure are therefore improved.

In accordance with some embodiments, a method for forming a device structure is provided. The method includes forming a first carbon-containing layer over a substrate and forming a hafnium-containing oxide layer over the first carbon-containing layer. The method also includes forming a second carbon-containing layer over the hafnium-containing oxide layer. The method further includes crystallizing the hafnium-containing oxide layer while the hafnium-containing oxide layer is between the first carbon-containing layer and the second carbon-containing layer.

In accordance with some embodiments, a method for forming a device structure is provided. The method includes forming a carbon-containing layer over a substrate. The method also includes forming a ferroelectric layer over the carbon-containing layer. The method further includes crystallizing the ferroelectric layer by simultaneously annealing the ferroelectric layer and the carbon-containing layer.

In accordance with some embodiments, a device structure is provided. The device structure includes a substrate and a carbon-containing layer over the substrate. The device structure also includes a crystallized ferroelectric layer over the carbon-containing layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure, comprising:
a substrate;
a carbon-containing layer over the substrate;
a crystallized ferroelectric layer extending along a surface of the carbon-containing layer, wherein the crystallized ferroelectric layer is as wide as or wider than the carbon-containing layer; and
a material layer interfacing the crystallized ferroelectric layer, wherein the material layer comprises a metal material or a semiconductor material.

2. The device structure as claimed in claim 1, wherein the crystallized ferroelectric layer is in direct contact with the carbon-containing layer.

3. The device structure as claimed in claim 16 further comprising:
a first electrode between the carbon-containing layer and the substrate, wherein the material layer is a second electrode.

4. The device structure as claimed in claim 1, further comprising:
source/drain electrodes electrically connected to the material layer, wherein the material layer is made of an oxide semiconductor material.

5. The device structure as claimed in claim 4, wherein the source/drain electrodes vertically extend across topmost surfaces of the material layer and the crystallized ferroelectric layer.

6. The device structure as claimed in claim 1, wherein the carbon-containing layer has opposite sidewalls, and the crystallized ferroelectric layer extends along the opposite sidewalls of the carbon-containing layer.

7. The device structure as claimed in claim 6, wherein the crystallized ferroelectric layer has a first sidewall, an upper surface, and a second sidewall, wherein the material layer extends along the first sidewall, the upper surface, and the second sidewall.

8. The device structure as claimed in claim 7, further comprising:
a metal gate stripe having a third sidewall and a fourth sidewall, wherein the carbon-containing layer extends along the third sidewall and the fourth sidewall.

9. The device structure as claimed in claim 7, wherein the material layer is wider than the crystallized ferroelectric layer.

10. A device structure, comprising:
a carbon-containing stripe;
a crystallized ferroelectric layer extending along a first sidewall, an upper surface, and a second sidewall of the carbon-containing layer; and
a semiconductor layer interfacing the crystallized ferroelectric layer.

11. The device structure as claimed in claim 10, wherein the semiconductor layer extends across an interface between the carbon-containing stripe and the crystallized ferroelectric layer.

12. The device structure as claimed in claim 10, further comprising:
a first electrode beside the semiconductor layer; and
a second electrode beside the semiconductor layer, wherein the carbon-containing stripe is laterally between the first electrode and the second electrode.

13. The device structure as claimed in claim 12, wherein the first electrode is taller than the carbon-containing stripe.

14. The device structure as claimed in claim 10, further comprising:
a metal gate stripe surrounded by the carbon-containing stripe.

15. The device structure as claimed in claim 10, wherein each of the crystallized ferroelectric layer and the semiconductor layer contains oxygen.

16. A device structure, comprising:
a substrate;
a carbon-containing layer over the substrate;
a crystallized ferroelectric layer over the carbon-containing layer; and
a material layer interfacing the crystallized ferroelectric layer, wherein the material layer and the carbon-containing layer are made of different materials.

17. The device structure as claimed in claim 16, further comprising:
a second material layer between the substrate and the carbon-containing layer, wherein the material layer and the second material layer comprise a metal material.

18. The device structure as claimed in claim 16, wherein the material layer is made of a semiconductor oxide material.

19. The device structure as claimed in claim 18, further comprising:
a first electrode over the material layer; and
a second electrode over the material layer.

20. The device structure as claimed in claim 18, further comprising:
a metal structure over the substrate, wherein the carbon-containing layer extends along a sidewall and a top surface of the metal structure.
